(19) United States
(12) Patent Application Publication
(10) Pub. No.: US 2026/0164546 A1
(43) Pub. Date: Jun. 11, 2026

(54) WIRING FORMING MEMBER, METHOD FOR FORMING WIRING LAYER, AND WIRING FORMED MEMBER

(71) Applicant: Resonac Corporation, Tokyo (JP)

(72) Inventors: Masashi OHKOSHI, Tokyo (JP); Yuka ITOH, Tokyo (JP); Kunihiko AKAI, Tokyo (JP); Nozomu TAKANO, Tokyo (JP); Hiroyuki IZAWA, Tokyo (JP); Daisuke FUJIMOTO, Tokyo (JP)

(21) Appl. No.: 18/858,162

(22) PCT Filed: Jan. 10, 2024
(86) PCT No.: PCT/JP2024/000316

§ 371 Date: Oct. 18, 2024

(30) Foreign Application Priority Data
Jan. 10, 2023 (JP) 2023-001504

(51) Int. Cl. H05K 1/02; H05K 1/09; H05K 3/46

(52) U.S. Cl. CPC H05K 1/0298; H05K 1/092; H05K 3/4655; H05K 2201/0364

(57) ABSTRACT

A wiring forming member 1 includes a metal layer 20 and an adhesive layer 10 disposed on the metal layer 20, in which the adhesive layer 10 includes conductive particles 12 and a thermosetting resin, the adhesive layer has a reaction rate of 90% or less when heated at 180° C. for 5 minutes, and a ratio [Dp/T] of an average particle diameter Dp of the conductive particles to a thickness T of the adhesive layer is 0.56 to 1.2.

### TECHNICAL FIELD

The present disclosure relates to a wiring forming member, a method for forming a wiring layer using the wiring forming member, and a wiring formed member.

### BACKGROUND ART

Patent Literature 1 discloses a method for manufacturing a printed wiring board incorporating an electronic component such as an IC chip.

### CITATION LIST

### Patent Literature

Patent Literature 1: Japanese Unexamined Patent Publication No. 2012-191204

### SUMMARY OF INVENTION

### Technical Problem

In the conventional method for manufacturing a component-embedded substrate, as illustrated in FIGS. 8(a) and 8(b), the insulating resin layers 102 and 103 are formed on both sides in the stacking direction of the electronic component 101 provided with the electrodes 101a. Thereafter, as illustrated in FIGS. 8(c) and 8(d), by performing drilling by laser, formation of a plating layer, electrode formation by etching, and the like, via electrodes 104 and 105 reaching the respective electrodes 101a of the electronic component 101 are formed in the respective insulating resin layers 102 and 103. Then, as illustrated in FIGS. 9(a) to 9(c), by repeating formation of the insulating resin layers 106 and 107, formation of the via electrode 108 by drilling with a laser and formation of a plating layer, electrode formation by etching, and the like, the component-embedded substrate 110 is formed. However, in such a method for manufacturing a component-embedded substrate, in order to form one conductive layer (via electrode) by performing many processing steps and form a plurality of conductive layers, it is necessary to repeat these processing steps, and the manufacturing process is very complicated.

Therefore, an adhesive in which a metal layer such as metal foil is laminated and which has conductive particles was examined as a member for forming wiring. According to such a wiring forming member, it can be expected that the wiring layer connected to the wiring is easily formed on the base material on which the wiring is formed through the process of arranging the wiring forming member such that the adhesive layer faces the base material with respect to the surface of the base material on which the wiring is formed, the process of thermocompression-bonding the wiring forming member to the base material, and the process of performing a patterning process on the metal layer.

However, as a result of evaluating the connection resistance between the wirings for the wiring formed member obtained by the above method, it has been found that the resistance value may become too high between some wirings. Such resistance unevenness leads to connection failure, leading to deterioration of yield in manufacturing of the component-embedded substrate.

Therefore, an object of the present disclosure is to provide a wiring forming member, a method for forming a wiring layer using the wiring forming member, and a wiring formed member capable of simplifying a process of forming a wiring layer connecting wirings while sufficiently suppressing occurrence of resistance unevenness.

### Solution to Problem

In order to solve the above problems, the present disclosure provides a wiring forming member, a method for forming a wiring layer, and a wiring formed member described below.

[1]A wiring forming member including a metal layer, and an adhesive layer disposed on the metal layer, in which the adhesive layer contains conductive particles and a thermosetting resin, the adhesive layer has a reaction rate of 90% or less when heated at 180° C. for 5 minutes, and a ratio [Dp/T] of an average particle diameter Dp of the conductive particles to a thickness T of the adhesive layer is 0.56 to 1.2.
[2] The wiring forming member according to above [1], in which the thermosetting resin contains an epoxy resin and a phenol resin.
[3] The wiring forming member according to above [2], in which the phenol resin has a hydroxyl equivalent of 300 g/eq or less.
[4] The wiring forming member according to any one of above [1] to [3], in which the adhesive layer further contains a filler.
[5] The wiring forming member according to any one of above [1] to [4], in which the adhesive layer further contains a maleimide compound.
[6] The wiring forming member according to any one of above [1] to [5], further including a release film.
[7]A wiring forming member in which an adhesive layer and a metal layer are provided separately, and the adhesive layer can adhere to the metal layer during use, in which the adhesive layer includes conductive particles and a thermosetting resin, the adhesive layer has a reaction rate of 90% or less when heated at 180° C. for 5 minutes, and a ratio [Dp/T] of an average particle diameter Dp of the conductive particles to a thickness T of the adhesive layer is 0.56 to 1.2.
[8] The wiring forming member according to above [7], in which the thermosetting resin contains an epoxy resin and a phenol resin.
[9] The wiring forming member according to above [8], in which the phenol resin has a hydroxyl equivalent of 300 g/eq or less.
[10] The wiring forming member according to any one of above [7] to [9], in which the adhesive layer further contains a filler.
[11] The wiring forming member according to any one of above [7] to [10], in which the adhesive layer further contains a maleimide compound.
[12]A method for forming a wiring layer, the method including a process of preparing the wiring forming member according to any one of above [1] to [11], a process of preparing a base material on which a wiring is formed, a process of arranging the wiring forming member such that the adhesive layer faces the base material with respect to a surface of the base material on which the wiring is formed to cover the wiring, a process of thermocompression-bonding the wiring forming member to the base material, and a process of performing patterning processing on the metal layer.
[13]A wiring formed member including a base material having a wiring, and a cured product of the adhesive layer of the wiring forming member according to any one of [1] to [11], the cured product being disposed on the base material to cover the wiring, in which the wiring is electrically connected to the metal layer of the wiring forming member or another wiring formed from the metal layer.

According to the wiring forming member according to above [1], it is possible to simplify the process of forming the wiring layer connecting the wirings while sufficiently suppressing the occurrence of resistance unevenness. In addition, it is presumed that such an effect is exhibited because the curing reaction of the adhesive layer proceeds for a long time, so that sufficient embedding and uniform curing are possible, the occurrence of bubbles or peeling is sufficiently suppressed during forming the wiring, and the conductive particles are easily captured between the wirings because the thickness of the adhesive layer is set in the above specific range.

In the case of the wiring forming member according to above [6], the wiring forming member can be easily handled as a member, and work efficiency when forming a wiring layer using the wiring forming member can be improved. As an example, the release film can be used by being disposed on a surface of the adhesive layer opposite to the metal layer.

According to the wiring forming member according to above [7], it is possible to achieve the same effects as those of the wiring forming member according to [1]. Furthermore, since the adhesive layer and the metal layer can be separately prepared (as a set of wiring forming members), it is possible to improve the degree of freedom in work when preparing the wiring layer using the wiring forming member, such as selecting a wiring forming member having a more optimal material configuration.

According to the forming method described in above [12], the processing process can be greatly simplified as compared with the conventional method. In addition, according to this forming method, the occurrence of resistance unevenness in the wiring layer can be sufficiently suppressed.

### Advantageous Effects of Invention

According to the present disclosure, it is possible to simplify a process of forming a wiring layer connecting wirings while sufficiently suppressing occurrence of resistance unevenness.

### BRIEF DESCRIPTION OF DRAWINGS

FIG. 1 is a cross-sectional view illustrating a wiring forming member according to an embodiment of the present disclosure.

FIG. 2(a) to 2(d) are views for sequentially illustrating a method for forming a wiring layer using the wiring forming member illustrated in FIG. 1.

FIGS. 3(a) to 3(c) are cross-sectional views illustrating a wiring forming member according to another embodiment of the present disclosure and a state where the wiring forming member is pressure-bonded.

FIG. 4 is a cross-sectional view illustrating a wiring forming member according to another embodiment of the present disclosure.

FIG. 5(a) to 5(d) are views for sequentially illustrating a method for forming a wiring layer using the wiring forming member illustrated in FIG. 4.

FIGS. 6(a) to 6(b) are cross-sectional views for illustrating an example of a case where a wiring layer is formed using the wiring forming member illustrated in FIG. 4.

FIGS. 7(a) to 7(b) are cross-sectional views for illustrating another example in a case where a wiring layer is formed using the wiring forming member illustrated in FIG. 4.

FIGS. 8(a) to 8(d) are cross-sectional views for sequentially illustrating a conventional method for manufacturing a component-embedded substrate.

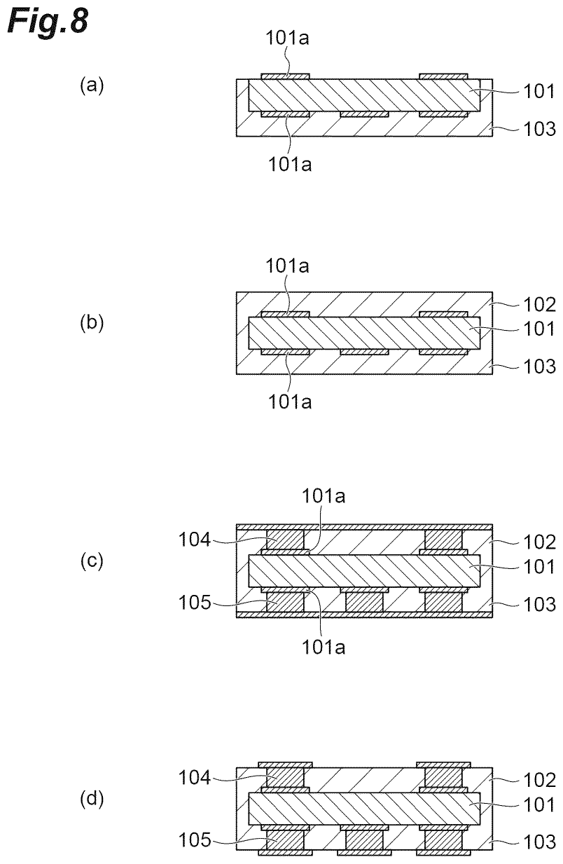

FIGS. 9(a) to 9(c) are cross-sectional views for sequentially illustrating a conventional method for manufacturing a component-embedded substrate, and illustrate processes following FIG. 8.

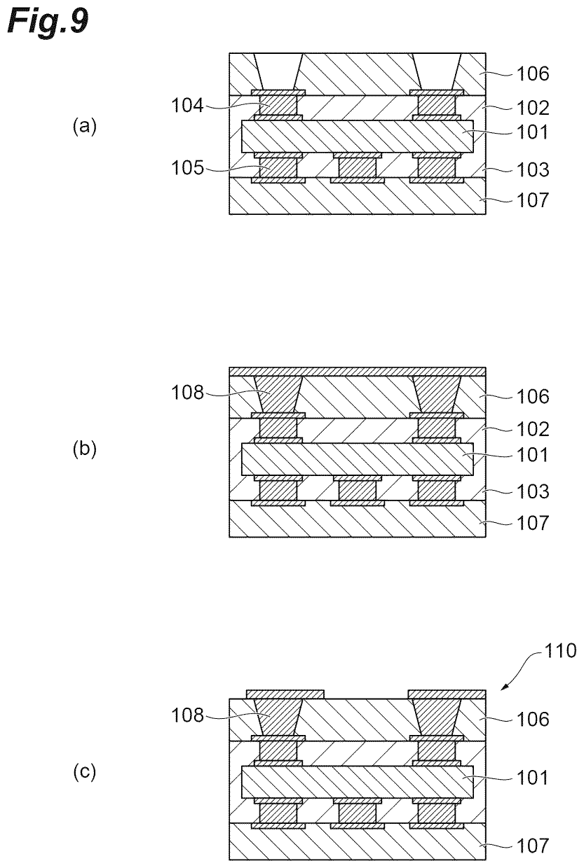

### DESCRIPTION OF EMBODIMENTS

Hereinafter, a wiring forming member and a method for forming a wiring layer using the wiring forming member according to an embodiment of the present disclosure will be described with reference to the drawings. In the following description, the same or corresponding portions will be denoted by the same reference numerals, and redundant description will be omitted. Furthermore, unless otherwise specified, the positional relationship such as up, down, left, and right is based on the positional relationship illustrated in the drawings. Furthermore, the dimensional ratios in the drawings are not limited to the illustrated ratios.

In the present specification, the numerical range indicated using “to” includes the numerical values stated before and after “to” as the minimum value and the maximum value, respectively. In addition, in the numerical ranges described in stages in the present specification, the upper limit value or the lower limit value stated in one numerical range may be replaced with the upper limit value or the lower limit value of the numerical range described in another stage. In addition, in a numerical range described in the present specification, an upper limit value or a lower limit value of the numerical range may be replaced with a value shown in examples.

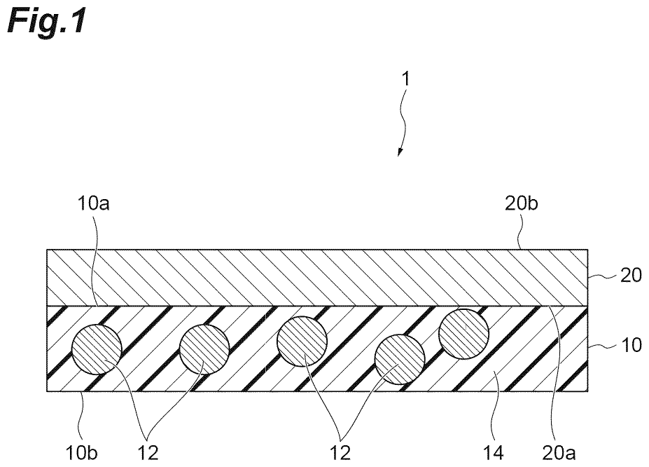

FIG. 1 is a cross-sectional view illustrating a wiring forming member according to an embodiment of the present disclosure. As illustrated in FIG. 1, a wiring forming member 1 includes an adhesive layer 10 and a metal layer 20. Although the wiring forming member 1 is not limited thereto, for example, the wiring forming member 1 is a member that can be used when a re-wiring layer, a build-up multilayer wiring board, a component-embedded substrate, or the like is prepared. In addition, the wiring forming member 1 may be used for EMI shielding or the like.

The adhesive layer 10 includes conductive particles 12 and an insulating adhesive component 14 in which the conductive particles 12 are dispersed. The adhesive component 14 of the adhesive layer 10 is defined as a solid content other than the conductive particles 12. The adhesive layer 10 may be in a B-stage state, that is, the semi-cured state, before the wiring layer is formed by the wiring forming member 1.

### [Configuration of Conductive Particles]

The conductive particles 12 are substantially spherical particles having conductivity, and include metal particles made of a metal such as Au, Ag, Ni, Cu, or solder, conductive carbon particles made of conductive carbon, or the like. The conductive particle 12 may be a coated conductive particle including a core containing non-conductive glass, ceramic, plastic (polystyrene or the like), or the like, and a coating layer containing the metal or conductive carbon and coating the core. Among these, the conductive particle 12 may be a metal particle formed of a hot-melting metal or a coated conductive particle including a core containing plastic and a coating layer containing metal or conductive carbon and coating the core. The conductive particles 12 may be copper particles from the viewpoint of making a short circuit of a circuit less likely to occur.

In one embodiment, the conductive particle 12 includes a core made of polymer particles (plastic particles) such as polystyrene and a metal layer covering the core. The surface of the polymer particle may be substantially entirely covered with the metal layer, and a part of the surface of the polymer particle may be exposed without being covered with the metal layer to the extent that the function as a connection material is maintained. The polymer particles may be, for example, particles containing a polymer containing at least one monomer selected from styrene and divinylbenzene as a monomer unit.

The metal layer may be formed of various metals such as Ni, Ni/Au, Ni/Pd, Cu, NiB, Ag, and Ru. The metal layer may be an alloy layer made of an alloy of Ni and Au, an alloy of Ni and Pd, or the like.

The metal layer may have a multilayer structure including a plurality of metal layers. For example, the metal layer may include a Ni layer and an Au layer. The metal layer may be prepared by plating, vapor deposition, sputtering, solder, or the like. The metal layer may be a thin film (for example, a thin film formed by plating, vapor deposition, sputtering, or the like).

The conductive particle 12 may have an insulating layer.

Specifically, for example, an insulating layer further covering the coating layer may be provided outside the coating layer in the conductive particles of the above embodiment including the core (for example, polymer particles) and the covering layer such as a metal layer covering the core. The insulating layer may be an outermost surface layer located on the outermost surface of the conductive particle. The insulating layer may be a layer formed of an insulating material such as silica or an acrylic resin.

The average particle diameter Dp of the conductive particles 12 may be 1 μm or more, 2 μm or more, or 5 μm or more from the viewpoint of excellent dispersibility and conductivity. The average particle diameter Dp of the conductive particles may be 50 μm or less, 30 μm or less, or 20 μm or less from the viewpoint of excellent dispersibility and conductivity. From the above viewpoint, the average particle diameter Dp of the conductive particles may be 1 to 50 μm, 5 to 30 μm, 5 to 20 μm, or 2 to 20 μm.

The maximum particle diameter of the conductive particles 12 may be smaller than the minimum interval between the electrodes in the wiring pattern (the shortest distance between the adjacent electrodes).

The maximum particle diameter of the conductive particles 12 may be 1 μm or more, 2 μm or more, or 5 μm or more from the viewpoint of excellent dispersibility and conductivity. The maximum particle diameter of the conductive particles may be 50 μm or less, 30 μm or less, or 20 μm or less from the viewpoint of excellent dispersibility and conductivity. From the above viewpoint, the maximum particle diameter of the conductive particles may be 1 to 50 μm, 2 to 30 μm, or 5 to 20 μm.

In the present specification, the particle diameter of 300 arbitrary particles (pcs) is measured by observation using a scanning electron microscope (SEM), the average value of the obtained particle diameters is taken as the average particle diameter Dp, and the largest value obtained is taken as the maximum particle diameter of the particles. In a case where the shape of the particles is not spherical, such as in a case where the particles have protrusions, the particle diameter of the particles is the diameter of a circle circumscribing the particles in the SEM image.

The content of the conductive particles 12 is determined according to the definition and the like of the electrode to be connected. For example, the blending amount of the conductive particles 12 is not particularly limited, but may be 0.1 vol % or more, 0.2 vol % or more, 1 vol % or more, 1.5 vol % or more, 2 vol % or more, 5 vol % or more, or 10 vol % or more based on the total volume of the adhesive component (component excluding the conductive particles in the adhesive composition). When the blending amount is within these ranges, resistance unevenness and a decrease in conductivity tend to be suppressed. The blending amount of the conductive particles 12 may be 30 vol % or less, 15 vol % or less, or 10 vol % or less based on the total volume of the adhesive component (component excluding the conductive particles 12 in the adhesive composition). When the blending amount is within these ranges, a short circuit of the circuit tends to be less likely to occur. The “% by volume” is determined based on the volume of each component before curing at 23° C., but the volume of each component can be converted from weight to volume using specific gravity. In addition, it is also possible to obtain an increased volume as the volume of the component by adding the component to a material obtained by adding an appropriate solvent (water, alcohol, or the like) that wets the component well without dissolving or swelling the component in a measuring cylinder or the like.

The adhesive layer 10 may contain 0.1 to 10 vol %, 1 to 5 vol %, or 1 to 3 vol % of copper particles as conductive particles from the viewpoint of sufficiently securing the conductivity of the wiring and making a short circuit of the circuit less likely to occur.

### [Configuration of Adhesive Layer/Adhesive Component]

The adhesive component 14 constituting the adhesive layer 10 contains a thermosetting component. Examples of the thermosetting component include a thermosetting resin, a curing agent, and a curing accelerator.

The thermosetting resin is a resin that exhibits curability by heat. Examples of the thermosetting resin include triazine resins such as epoxy resins, polyimide resins and melamine resins, phenol resins, and modified products of these resins. Among them, an epoxy resin may be used from the viewpoint of sufficiently suppressing generation of bubbles or peeling at the time of forming wiring.

The adhesive component can contain an epoxy resin and a phenol resin as thermosetting components from the viewpoint of sufficiently suppressing generation of bubbles or peeling at the time of forming wiring and making resistance unevenness less likely to occur.

The epoxy resin may be a compound having two or more epoxy groups in the molecule, and examples thereof include a bisphenol A-type epoxy resin, a bisphenol F-type epoxy resin, a bisphenol S-type epoxy resin, a biphenyl-type epoxy resin, a biphenyl novolac-type epoxy resin, a phenol novolac-type epoxy resin, a cresol novolac-type epoxy resin, a bisphenol A novolac-type epoxy resin, a bisphenol F novolac-type epoxy resin, a dicyclopentadiene-type epoxy resin, an alicyclic epoxy resin, an aliphatic chain epoxy resin, a glycidyl ester-type epoxy resin, an isocyanurate-type epoxy resin, a hydantoin-type epoxy resin, a polyfunctional phenol glycidyl ether compound, a bifunctional alcohol glycidyl ether compound, and hydrogenated products thereof. Among them, from the viewpoint of handleability and availability, a novolac-type epoxy resin such as a biphenyl novolac-type epoxy resin, a phenol novolac-type epoxy resin, a cresol novolac-type epoxy resin, a bisphenol A novolac-type epoxy resin, or a bisphenol F novolac-type epoxy resin may be used. One kind of epoxy resin may be used alone, or two or more kinds thereof may be used in combination.

The adhesive component may contain a compound having three or more epoxy groups in one molecule as an epoxy resin from the viewpoint of securing adhesive strength and heat resistance.

The epoxy resin may have an epoxy equivalent of 100 to 1000 g/eq, 125 to 900 g/eq, or 150 to 800 g/eq from the viewpoint of securing adhesive strength and heat resistance and good reactivity. The epoxy equivalent is determined by a method standardized in JIS (K7236:2001).

The content of the epoxy resin in the adhesive component may be 5 to 95 mass %, 10 to 90 mass %, 15 to 85 mass %, or 40 to 60 mass % based on the total amount of the adhesive component (the total amount of the solid content other than the conductive particles 12 in the adhesive layer 10).

The phenol resin functions as a curing agent for the epoxy resin. Examples of the phenol resin include novolac type phenol resins such as phenol novolac, cresol novolac, bisphenol A novolac, bisphenol F novolac, and catechol novolac, and those obtained by substituting these aromatic rings with an alkyl group. The phenol resin may be used alone or in combination of two or more thereof.

The adhesive component may contain a compound having three or more phenol groups or cresol groups in one molecule as a phenol resin from the viewpoint of securing adhesive strength and heat resistance.

As such a compound, a phenol novolac-type phenol resin, a cresol novolac-type phenol resin, a bisphenol A novolac-type phenol resin, a bisphenol F novolac-type phenol resin, or the like may be used from the viewpoint of handleability and availability.

The hydroxyl group equivalent of the phenol resin may be 300 g/eq or less or 250 g/eq or less from the viewpoint of suppressing the occurrence of bubbles or peeling at the time of forming wiring and making resistance unevenness less likely to occur, and may be 50 g/eq or more or 100 g/eq or more from the viewpoint of ease of handling and good reactivity.

The hydroxyl group equivalent of the phenol resin is determined by the following measurement method.

### <Method for Measuring Hydroxyl Group Equivalent>

1 g of a sample is weighed precisely into a round-bottom flask, and 5 mL of acetic anhydride and a pyridine test solution are further weighed accurately. Next, the flask is then equipped with an air cooler and heated at 100° C. for 1 hour. After cooling the flask, 1 mL of water is added, and the flask is heated again at 100° C. for 10 minutes. After re-cooling the flask, the air cooler and the neck of the flask were washed with 5 mL of neutralized methanol, and 1 mL of a phenolphthalein reagent was added. The thus-obtained solution is titrated using a 0.1 mol/L potassium hydroxide-ethanol solution to determine the hydroxyl value. From the obtained hydroxyl value, the hydroxyl equivalent (g/eq) in terms of mass per 1 mol (1 eq) of hydroxyl group is calculated.

The content of the phenol resin in the adhesive component can be set so that the number of hydroxyl groups of the phenol resin is 0.5 to 2 per epoxy group of the epoxy resin.

The adhesive component containing the epoxy resin and the phenol resin may further contain a thermosetting resin other than the epoxy resin, or may further contain a curing agent other than the phenol resin. As the thermosetting resin other than the epoxy resin, a triazine resin such as a polyimide resin or a melamine resin, a modified product of these resins, and the like can be used. Examples of the curing agent other than the phenol resin include amines, amides, acid anhydrides, acids, and imidazoles.

In addition, in the wiring forming member of the present embodiment, the adhesive component may further contain a maleimide compound from the viewpoint of sufficiently suppressing generation of bubbles or peeling during wiring formation.

In this case, the adhesive component may contain an epoxy resin as the thermosetting resin from the viewpoint of sufficiently suppressing generation of bubbles or peeling at the time of forming the wiring. The content of the epoxy resin in the adhesive component at this time may be 5 to 95 mass %, 10 to 90 mass %, 15 to 85 mass %, or 15 to 40 mass % with respect to the total amount of the adhesive component (the total amount of solid components other than the conductive particles 12 in the adhesive layer 10).

The maleimide compound is a compound having at least one N-substituted maleimide group in one molecular structure. The maleimide compound may contain, for example, at least one selected from the group consisting of a polymaleimide compound (m1) (hereinafter, the “(m1) component“may be referred to”) having at least two N-substituted maleimide groups in one molecular structure and a derivative thereof. Examples of the “derivative thereof” include an addition reaction product of the polymaleimide compound (m1) and an amine compound such as a diamine compound described later. Since the maleimide compound has low reactivity, it is expected that the curing reaction proceeds slowly by the adhesive component 14 containing the maleimide compound and the maleimide compound. When the curing reaction proceeds slowly, a sufficient flow time can be secured, and generation of bubbles or peeling can be sufficiently suppressed at the time of forming wiring.

Examples of the (m1) component include N,N′-ethylenebismaleimide, N,N′-hexamethylenebismaleimide, N,N′-(1,3-phenylene)bismaleimide, N,N′-[1,3-(2-methylphenylene)]bismaleimide, N,N′-[1,3-(4-methylphenylene)]bismaleimide, N,N′-(1,4-phenylene)bismaleimide, bis(4-maleimidophenyl)methane, bis(3-methyl-4-maleimidophenyl)methane, 3,3-dimethyl-5,5-diethyl-4,4-diphenylmethane bismaleimide, bis(4-maleimidophenyl)ether, bis(4-maleimidophenyl)sulfone, bis(4-maleimidophenyl)sulfide, bis(4-maleimidophenyl)ketone, bis(4-maleimidocyclohexyl)methane, 1,4-bis(4-maleimidophenyl)cyclohexane, 1,4-bis(maleimidomethyl)cyclohexane, 1,4-bis(maleimidomethyl)benzene, 1,3-bis(4-maleimidophenoxy)benzene, 1,3-bis(3-maleimidophenoxy)benzene, bis[4-(3-maleimidophenoxy)phenyl]methane, bis[4-(4-maleimidophenoxy)phenyl]methane, 1,1-bis[4-(3-maleimidophenoxy)phenyl]ethane, 1,1-bis[4-(4-maleimidophenoxy)phenyl]ethane, 1,2-bis[4-(3-maleimidophenoxy)phenyl]ethane, 1,2-bis[4-(4-maleimidophenoxy)phenyl]ethane, 2,2-bis[4-(3-maleimidophenoxy)phenyl]propane, 2,2-bis[4-(4-maleimidophenoxy)phenyl]propane, 2,2-bis[4-(3-maleimidophenoxy)phenyl]butane, 2,2-bis[4-(4-maleimidophenoxy)phenyl]butane, 2,2-bis[4-(3-maleimidophenoxy)phenyl]-1,1,1,3,3,3-hexafluoropropane, 2,2-bis[4-(4-maleimidophenoxy)phenyl]-1,1,1,3,3,3-hexafluoropropane, 4,4-bis(3-maleimidophenoxy)biphenyl, 4,4-bis(4-maleimidophenoxy)biphenyl, bis[4-(3-maleimidophenoxy)phenyl]ketone, bis[4-(4-maleimidophenoxy)phenyl]ketone, 2,2-bis(4-maleimidophenyl)disulfide, bis(4-maleimidophenyl)disulfide, bis[4-(3-maleimidophenoxy)phenyl]sulfide, bis[4-(4-maleimidophenoxy)phenyl]sulfide, bis[4-(3-maleimidophenoxy)phenyl]sulfoxide, bis[4-(4-maleimidophenoxy)phenyl]sulfoxide, bis[4-(3-maleimidophenoxy)phenyl]sulfoxide, bis[4-(4-maleimidophenoxy)phenyl]sulfone, bis[4-(3-maleimidophenoxy)phenyl]ether, bis[4-(4-maleimidophenoxy)phenyl]ether, 1,4-bis[4-(4-maleimidophenoxy)-α,α-dimethylbenzyl]benzene, 1,3-bis[4-(4-maleimidophenoxy)-α,α-dimethylbenzyl]benzene, 1,4-bis[4-(3-maleimidophenoxy)-α,α-dimethylbenzyl]benzene, 1,3-bis[4-(3-maleimidophenoxy)-α,α-dimethylbenzyl]benzene, 1,4-bis[4-(4-maleimidophenoxy)-3,5-dimethyl-α,α-dimethylbenzyl]benzene, 1,3-bis[4-(4-maleimidophenoxy)-3,5-dimethyl-α,α-dimethylbenzyl]benzene, 1,4-bis[4-(3-maleimidophenoxy)-3,5-dimethyl-α,α-dimethylbenzyl]benzene, 1,3-bis[4-(3-maleimidophenoxy)-3,5-dimethyl-α,α-dimethylbenzyl]benzene, and polyphenylmethane maleimide (for example, trade name: BMI-2300 or the like, manufactured by Daiwa Fine Chemicals Co., Ltd.). One maleimide compound may be used alone, or two or more maleimide compounds may be used in combination.

Among these maleimide compounds, bis(4-maleimidophenyl)methane, bis(4-maleimidophenyl)sulfone, N,N′-(1,3-phenylene)bismaleimide, 2,2-bis(4-(4-maleimidophenoxy)phenyl)propane, or polyphenylmethane maleimide, which has a high reaction rate and can have higher heat resistance, is preferable, and bis(4-maleimidophenyl)methane is particularly preferable from the viewpoint of solubility in a solvent.

The maleimide compound may contain a derivative of the polymaleimide compound (m1) from the viewpoint of solubility in an organic solvent, compatibility, and adhesiveness to metal foil. The derivative of the polymaleimide compound (m1) may contain, for example, a modified polymaleimide compound (M) having a structural unit derived from the polymaleimide compound (m1) and a structural unit derived from an amine compound (m2) having an amino group (hereinafter, the “(m2) component” may be referred to.”). The modified polymaleimide compound (M) can also be referred to as an addition reaction product of the (m1) component and the (m2) component. The structural unit derived from the (m1) component and the structural unit derived from the (m2) component contained in the modified polymaleimide compound (M) may each consist of one kind or a combination of two or more kinds.

The modified polymaleimide compound (M) may be a compound having a structure represented by Formula (1) below obtained by addition reaction between a maleimide group of the (m1) component and an amino group of the (m2) component. In Formula (1), * represents a bonding position.

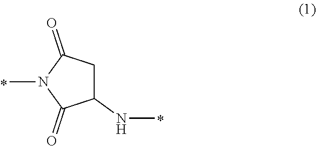

The (m2) component is preferably an amine compound (polyamine compound) having at least two amino groups, and may be a diamine compound having two amino groups. Examples of the (m2) component include aromatic diamine compounds such as 4,4′-diaminodiphenylmethane, 4,4′-diamino-3,3′-dimethyldiphenylmethane, 3,3′-diethyl-4,4′-diaminodiphenylmethane, 4,4′-diaminodiphenyl ether, 4,4′-diaminodiphenylsulfone, 3,3′-diaminodiphenylsulfone, 4,4′-diaminodiphenyl ketone, 4,4′-diaminobiphenyl, 3,3′-dimethyl-4,4′-diaminobiphenyl, 2,2′-dimethyl-4,4′-diaminobiphenyl, 3,3′-dihydroxybenzidine, 2,2-bis(3-amino-4 hydroxyphenyl)propane, 3,3′-dimethyl-5,5′-diethyl-4,4′-diaminodiphenylmethane, 2,2-bis(4-aminophenyl)propane, 2,2-bis[4-(4-aminophenoxy)phenyl]propane, 1,3-bis(3-aminophenoxy)benzene, 1,3-bis(4-aminophenoxy)benzene, 1,4-bis(4-aminophenoxy)benzene, 4,4′-bis(4-aminophenoxy)biphenyl, 1,3-bis[1-[4-(4-aminophenoxy)phenyl]-1-methylethyl]benzene, 1,4-bis[1-[4-(4-aminophenoxy)phenyl]-1-methylethyl]benzene, 4,4′-[1,3-phenylenebis(1-methylethylidene)]bisaniline, 4,4′-[1,4-phenylenebis(1-methylethylidene)]bisaniline, 3,3′-[1,3-phenylenebis(1-methylethylidene)]bisaniline, bis[4-(4-aminophenoxy) phenyl]sulfone, bis[4-(3-aminophenoxy)phenyl]sulfone, and 9,9-bis(4-aminophenyl)fluorene; amine compounds having a siloxane skeleton, or the like.

Among them, the (m2) component may be an amine compound having a siloxane skeleton from the viewpoint of low thermal expansion.

That is, the modified polymaleimide compound (M) may have a structural unit derived from the polymaleimide compound (m1) and a structural unit derived from an amine compound having a siloxane skeleton.

The (m2) component may be a compound represented by General Formula (2) below.

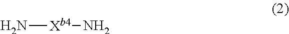

In Formula (2), X^{b4} represents a divalent organic group.

From the viewpoint of low thermal expansion, the (m2) component may contain an amine compound having a siloxane skeleton in which X^{b4} in General Formula (2) has a structural unit represented by General Formula (3) below. The (m2) component may contain an amine compound having a siloxane skeleton in which X^{b4} has a structural unit (or group) represented by General Formula (4) below.

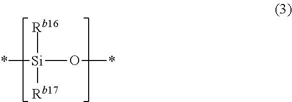

In Formula (3), R^{b16} and R^{b17} each independently represent an alkyl group, a phenyl group, or a substituted phenyl group having 1 to 5 carbon atoms. * indicates a binding position.

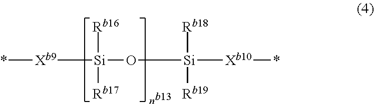

In Formula (4), Rb¹⁶ and R^{b17} have the same meaning as R^{b16} and R^{b17} in Formula (3) below, and a plurality of R^{b16} and R^{b17} may be the same or different. R^{b18} and R^{b19} each independently represent an alkyl group, a phenyl group, or a substituted phenyl group having 1 to 5 carbon atoms. X^{b9} and X^{b10} each independently represent a divalent organic group, and n^{b13} represents an integer of 2 to 100.

Examples of the substituent in the substituted phenyl group represented by R^{b16}, R^{b17}, R^{b18}, and R^{b19} include an alkyl group having 1 to 5 carbon atoms, an alkenyl group having 2 to 5 carbon atoms, and an alkynyl group having 2 to 5 carbon atoms.

Examples of the divalent organic group represented by X^{b9} and X^{b10} include an alkylene group, an alkenylene group, an alkynylene group, an arylene group, —O—, or a divalent linking group in which these groups are combined.

The content of the structural unit derived from the component (m1) in the modified polymaleimide compound (M) is not particularly limited, but may be 50 to 95 mass %, 70 to 92 mass %, or 75 to 90 mass %.

The content of the structural unit derived from the component (m2) in the modified polymaleimide compound (M) is not particularly limited, but may be 5 to 50 mass %, 8 to 30 mass %, or 10 to 25 mass %.

The total content of the structural unit derived from the (m1) component and the structural unit derived from the (m2) component in the modified polymaleimide compound (M) is not particularly limited, but may be 80 mass % or more, 90 mass % or more, 95 mass % or more, or 100 mass % (that is, it is composed of only a structural unit derived from the (m1) component and a structural unit derived from the (m2) component).

The content of the maleimide compound in the adhesive component may be 5 to 95 mass %, 10 to 90 mass %, or 15 to 85 mass % based on the total amount of the adhesive component (the total amount of the solid content other than the conductive particles 12 in the adhesive layer 10).

Examples of the curing accelerator include imidazole-based compounds, organophosphorus compounds, tertiary amines, and quaternary ammonium salts. The curing accelerator may be used singly or in combination of two or more kinds thereof. The adhesive component may contain an imidazole-based compound as a curing accelerator from the viewpoint that the temperature and time at the time of use (for example, the heating temperature and the heating time at the time of thermocompression-bonding) can be arbitrarily adjusted.

The content of the curing accelerator in the adhesive component may be 0.001 to 10 mass % based on the total amount of the adhesive component.

The adhesive component 14 may contain other components other than the thermosetting component described above. As other components, a filler, an antioxidant, a film-forming material, a softener, an anti-aging agent, a colorant, a flame retardant, a thixotropic agent, a coupling agent, and the like may be further contained.

Examples of the filler include inorganic fillers and organic fillers. Examples of the inorganic filler include alumina, silica, titanium oxide, clay, calcium carbonate, aluminum carbonate, magnesium silicate, aluminum silicate, mica, short glass fibers, aluminum borate, and silicon carbide. Examples of the organic filler include silicone particles, methacrylate butadiene styrene particles, acrylic silicone particles, polyamide particles, polyimide particles, and the like. The filler may be used singly or in combination of two or more kinds thereof.

The adhesive component can contain silica particles as a filler from the viewpoints of improvement of heat resistance, improvement of mechanical properties, and adjustment of fluidity during use (for example, during thermocompression-bonding).

The maximum diameter of the filler may be less than the particle diameter of the conductive particles 12, or may be 0.001 to 10 μm.

The content of the filler may be 5 parts by volume to 60 parts by volume with respect to 100 parts by volume of the adhesive component. When the content of the filler is 5 parts by volume to 60 parts by volume, good connection reliability tends to be obtained.

Examples of the antioxidant include quinone derivatives such as benzoquinone and hydroquinone, phenol derivatives (hindered phenol derivatives) such as 4-methoxyphenol and 4-t-butylcatechol, aminoxyl derivatives such as 2,2,6,6-tetramethylpiperidine-1-oxyl and 4-hydroxy-2,2,6,6-tetramethylpiperidine-1-oxyl, and hindered amine derivatives such as tetramethylpiperidyl methacrylate.

The content of the antioxidant may be 0.01 mass % to 5 mass % or 0.1 mass % to 3 mass % based on the total amount of the adhesive components.

As the film-forming material, a thermoplastic resin is suitably used, and examples thereof include a phenoxy resin, a polyvinyl formal resin, a polystyrene resin, a polyvinyl butyral resin, a polyester resin, a polyamide resin, a xylene resin, a polyurethane resin, a polyacrylic resin, and a polyester urethane resin. Further, these polymers may contain a siloxane bond or a fluorine substituent. These resins can be used alone or as a mixture of two or more thereof. Among the above resins, a phenoxy resin may be used from the viewpoint of adhesive strength, compatibility, heat resistance, and mechanical strength.

As the molecular weight of the thermoplastic resin is larger, the film formability can be easily obtained, and the melt viscosity that affects the fluidity of the film can be set in a wide range. The molecular weight of the thermoplastic resin may be 5000 to 150,000 or 10,000 to 80,000 in terms of a weight average molecular weight. When the weight average molecular weight is 5000 or more, good film formability is easily obtained, and when the weight average molecular weight is 150,000 or less, good compatibility with other components is easily obtained.

In the present disclosure, the weight average molecular weight refers to a value measured by gel permeation chromatography (GPC) using a calibration curve by standard polystyrene under the following conditions.

### (Measurement Conditions)

Device: GPC-8020 manufactured by TOSOH CORPORATION
Detector: RI-8020 manufactured by TOSOH CORPORATION
Column: Gelpack GLA160S+GLA150S manufactured by Hitachi Chemical Company, Ltd.
Sample concentration: 120 mg/3 mL
Solvent: Tetrahydrofuran
Injection amount: 60 μL
Pressure: 2.94×106 Pa (30 kgf/cm²)
Flow rate: 1.00 mL/min

The content of the film-forming material may be 0.5 to 75 mass % or 1 to 50 mass % based on the total amount of the adhesive components.

The adhesive component 14 may be substantially free of a highly reactive radical polymerizable compound such as an acrylic compound, a methacrylic compound, a styrene compound, and a vinyl compound from the viewpoint of improving the storage stability and the connection reliability. The phrase “substantially free of” means that the content based on the total amount of the adhesive component is 1% by mass or less. The content of the compound in the adhesive component may be 0.5 mass % or less or 0 mass % with respect to the total amount of the adhesive component.

From the viewpoint of making resistance unevenness less likely to occur, the adhesive layer 10 may have a reaction rate of 90% or less, 85% or less, 80% or less, or 70% or less when heated at 180° C. for 5 minutes.

The above reaction rate means a value determined by the following measurement method.

[Measurement of Reaction Rate when Heating at 180° C. For 5 Minutes]

A part of the adhesive layer is scraped off to obtain two pre-heating evaluation samples 5 mg. Next, one of the pre-heating evaluation samples is heated at 180° C. for 5 minutes to obtain a post-heating evaluation sample. For each of the sample for evaluation before heating and the sample for evaluation after heating, the calorific value of DSC is measured at a temperature rising rate of 2° C./min in a measurement temperature range of 30° C. to 250° C. under a nitrogen flow using a differential scanning calorimetry (DSC) device (Product name DSC7, manufactured by PerkinElmer Japan). Based on the measured calorific value of DSC, the reaction rate at the time of heating at 180° C. for 5 minutes is determined from the following formula.

$$Reaction rate = ( C x - C y ) \times 100 / Cx$$

[In the formula, Cx represents a DSC calorific value (J/g) of the evaluation sample before heating, and Cy represents a DSC calorific value (J/g) of the evaluation sample after heating.]

The reaction rate when the adhesive layer is heated at 180° C. for 5 minutes can be reduced by, for example, blending the above-described phenol resin or maleimide compound, not blending a curing accelerator, or selecting a curing accelerator having a high reaction start temperature.

From the viewpoint of making resistance unevenness less likely to occur, the ratio [Dp/T] of the average particle diameter Dp of the conductive particles to the thickness T of the adhesive layer may be 0.56 to 1.2, 0.6 to 1.15, or 0.65 to 1.1.

The thickness of the adhesive layer may be 1 to 70 μm, 2 to 60 μm, or 3 to 50 μm.

### [Configuration of Metal Layer]

A surface roughness Rz of the surface opposite to one surface of the metal layer 20 may be equal to or different from each other. The metal layer 20 has a thickness of, for example, 5 μm to 200 μm. The thickness of the metal layer here is a thickness including the surface roughness Rz. The metal layer 20 is, for example, copper foil, aluminum foil, nickel foil, stainless steel, titanium, or platinum.

The adhesive layer 10 is disposed on a first surface 20a of the metal layer 20. The surface roughness Rz of the first surface 20a of the metal layer 20 may be 0.3 μm or more, 0.5 μm or more, or 1.0 μm or more. In addition, the surface roughness Rz of the first surface 20a of the metal layer 20 may be 50 μm or less, 40 μm or less, 30 μm or less, 20 μm or less, less than 20 μm, 17 μm or less, 10 μm or less, 8.0 μm or less, 5.0 μm or less, or 3.0 μm or less. The surface roughness Rz of the first surface 20a of the metal layer 20 may be, for example, 0.3 μm or more and 20 μm or less, 0.3 μm or more and less than 20 μm, and more specifically, 0.5 μm or more and 10 μm or less. The surface roughness Rz of a second surface 20b of the metal layer 20 may be, for example, 20 μm or more, and may be coarser than the surface roughness Rz of the first surface 20a, may be the same surface roughness as the first surface 20a, or may not be coarser than the surface roughness Rz of the first surface 20a. In a case where the surface roughness Rz of the first surface 20a of the metal layer 20 is too smooth (for example, the surface roughness Rz is 0.2 μm), the adhesiveness between the metal layer 20 and the adhesive layer 10 cannot be maintained for a long period of time and may be peeled off. Therefore, the surface roughness Rz of the first surface 20a of the metal layer 20 may be 0.3 μm or more. However, the surface roughness Rz of the first surface 20a of the metal layer 20 may be made smaller than 0.3 μm by adopting a material or a connection configuration capable of securing adhesiveness.

The surface roughness Rz means a ten-point average roughness Rzjis measured in accordance with a method specified in JIS standard (JIS B 0601-2001), and refers to a value measured using a commercially available surface roughness shape measuring instrument. For example, measurement can be performed using a nano search microscope (“SFT-3500” manufactured by Shimadzu Corporation).

Here, the relationship between the average particle diameter Dp of the conductive particles 12 and the surface roughness Rz of the first surface 20a of the metal layer 20 will be described below. In the present embodiment, “surface roughness/average particle diameter” that is a ratio of the surface roughness Rz of the first surface 20a of the metal layer 20 to the average particle diameter Dp of the conductive particles 12 may be 0.03 or more, 0.04 or more, 0.05 or more, 0.06 or more, 0.1 or more, 0.2 or more, 0.3 or more, 0.5 or more, or 1 or more. The ratio “surface roughness/average particle diameter”, which is the ratio of surface roughness Rz of the first surface 20a of the metal layer 20 to the average particle diameter Dp of the conductive particles 12, may be 3 or less, 2 or less, 1.7 or less, or 1.5 or less. The ratio “surface roughness/average particle diameter”, which is the ratio of the surface roughness Rz of the first surface 20a of the metal layer 20 to the average particle diameter Dp of the conductive particles 12, may be, for example, 0.05 or more and 3 or less, and more specifically, may be 0.06 or more and 2 or less. In the present embodiment, the surface roughness Rz of the first surface 20a of the metal layer 20 and the average particle diameter Dp of the conductive particles 12 may be managed such that the ratio “surface roughness/average particle diameter” of the surface roughness Rz of the first surface 20a of the metal layer 20 to the average particle diameter Dp of the conductive particles 12 falls within the range of 0.05 to 3.

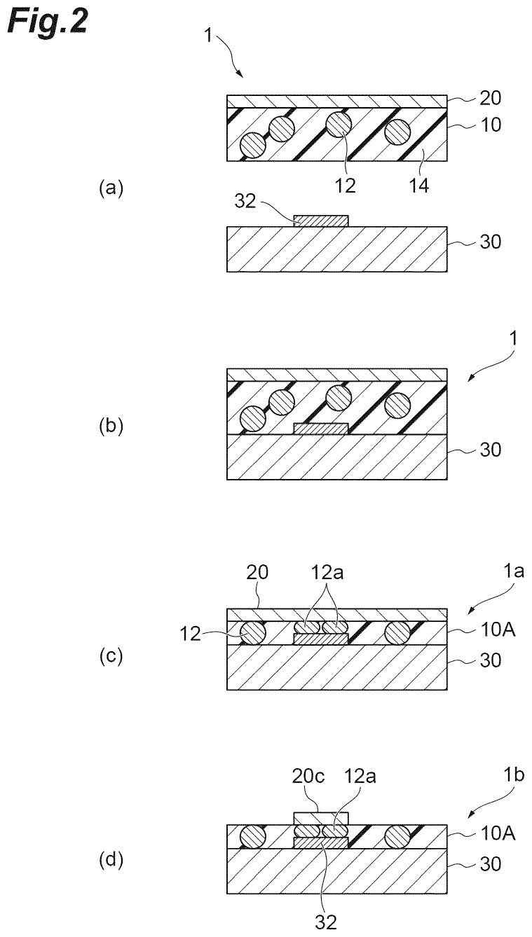

As another aspect, the present disclosure relates to a method for forming a wiring layer using a wiring forming member. A method for forming a wiring layer using the wiring forming member 1 described above will be described with reference to FIG. 2. FIGS. 2(a) to 2(d) are views illustrating a method for forming a wiring layer using the wiring forming member illustrated in FIG. 1.

First, as illustrated in FIG. 2(a), the wiring forming member 1 is prepared. Furthermore, a base material 30 on which a wiring 32 is formed is prepared. Then, the wiring forming member 1 is disposed such that the adhesive layer 10 side of the wiring forming member 1 faces the base material 30. Thereafter, as illustrated in FIG. 2(b), lamination is performed to cover the wiring 32, and the wiring forming member 1 is attached onto the base material 30.

Subsequently, as illustrated in FIG. 2(c), predetermined heating and pressurization are performed on the wiring forming member 1, and pressure bonding is performed on the base material 30. At this time, when the first surface 20a of the metal layer 20 of the wiring forming member 1 is flat, the conductive particles 12 required to ensure conductivity can be more reliably deformed into flat conductive particles 12a. In a pressure-bonded wiring forming member 1a, the conductive particles 12a flattened on the wiring 32 (thereby, the insulating layer is broken to expose the conduction portion) are disposed, and reliable electrical conduction between the metal layer 20 and the wiring 32 is achieved. At this time, the adhesive layer 10 is also crushed to become a thinner adhesive layer 10A.

Subsequently, as illustrated in FIG. 2(d), predetermined patterning processing (for example, etching processing) is performed on the metal layer 20, and processing is performed into a predetermined wiring pattern 20c (another wiring). At this time, the second surface 20b of the metal layer 20 may be treated to be a smooth surface. The above-described processing steps of FIG. 2(a) to FIG. 2(d) may be repeated a predetermined number of times to form the wiring layer.

That is, a method for forming a wiring layer using a wiring forming member includes a process of preparing a wiring forming member, a process of preparing a base material on which a wiring is formed, a process of arranging the wiring forming member such that an adhesive layer side faces a substrate with respect to a surface of the base material on which the wiring is formed to cover the wiring, a process of thermocompression-bonding the wiring forming member to the base material, and a process of performing patterning processing on the metal layer.

Thus, a wiring formed member 1b is formed. The wiring formed member 1b includes the base material 30 having the wiring 32, and the cured product of an adhesive component 14 of the wiring forming member 1 (an adhesive layer of the wiring forming member subjected to thermocompression-bonding) disposed on the base material 30 to cover the wiring 32. In the wiring formed member 1b, the wiring 32 and the metal layer 20 of the wiring forming member 1 or the wiring 20c formed (for example, etched) from the metal layer 20 are electrically connected by the conductive particles 12a. When the processing steps of FIG. 2(a) to (d) are repeated a predetermined number of times, the wiring formed member 1b may have a configuration including a plurality of wiring layers (layers in which the above-described wirings are connected to each other).

As described above, according to the method for forming the wiring layer using the wiring forming member 1 according to the present embodiment, the process for forming the wiring layer connecting the wirings can be simplified as compared with the conventional process for performing laser processing, filled plating processing, and the like. In addition, the formed wiring layer can be easily thinned.

Furthermore, according to the method for forming a wiring layer using the wiring forming member 1 according to the present embodiment, when the adhesive layer 10 has the above-described reaction rate, and the ratio [Dp/T] of the average particle diameter Dp of the conductive particles 12 to the thickness T of the adhesive layer 10 is 0.56 to 1.2, a wiring layer in which resistance unevenness is suppressed can be formed.

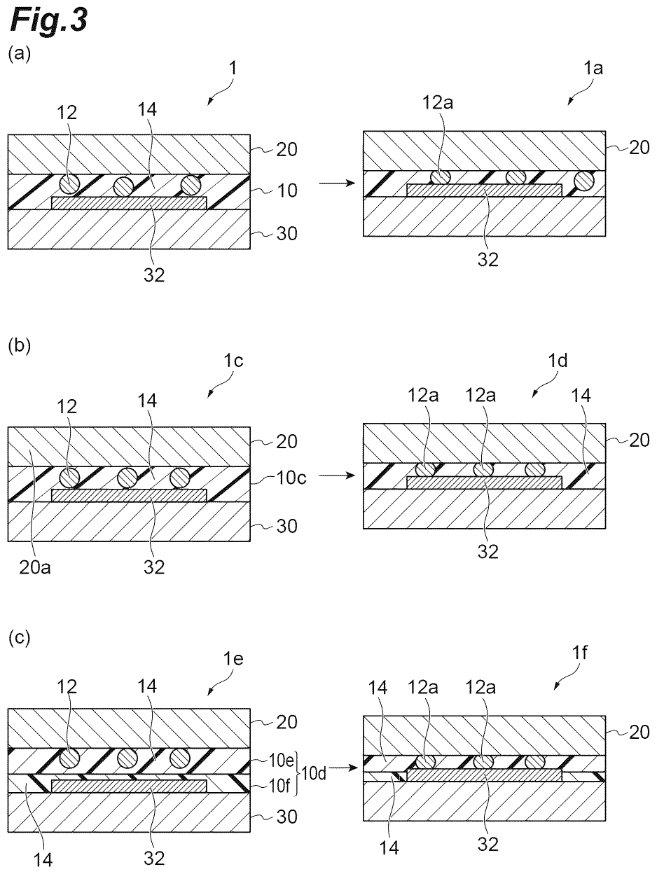

Although the embodiments of the present disclosure have been described in detail above, the present disclosure is not limited to the above embodiments, and can be applied to various embodiments. For example, in the above embodiment, as illustrated in FIG. 3(a), in the wiring forming member 1, the conductive particles 12 are randomly or on average dispersed in the adhesive layer 10, but as illustrated in FIG. 3(b), the conductive particles 12 may be arranged (localized) on the metal layer 20 side. In this case, in the adhesive layer 10, the conductive particles 12 may not be exposed on the second surface 10b opposite to the metal layer 20, and the thickness of the adhesive layer 10 existing between the conductive particles 12 and the first surface 20a of the metal layer 20 may be 0 μm or more than 0.1 μm and 1 μm or less. In this case, since the conductive particles 12 are arranged on the metal layer 20 side, the conductive particles 12 can be more reliably crushed into a flat shape by the metal layer 20 in a wiring layer 1d. In addition, by unevenly distributing the conductive particles 12 on the metal layer 20 side as described above, the trapping rate of the conductive particles 12 on the wiring (electrode) or the like can be improved. That is, conduction can be made more stable. The distance between the conductive particle 12 and the first surface 20a of the metal layer 20 (the thickness of the adhesive layer 10 present therebetween) means the shortest distance from the surface of the metal layer 20 in contact with the adhesive layer 10 to the surface of the conductive particle 12, and is, for example, an average value at arbitrary 30 points. In addition, this distance is measured using a scanning electron microscope (SEM, trade name: SE-8020, manufactured by Hitachi High-Tech Corporation) by sandwiching the wiring forming member between two sheets of glass (thickness: about 1 mm), casting with a resin composition including 100 g of a bisphenol A-type epoxy resin (Trade name: JER811, manufactured by Mitsubishi Chemical Group Corporation) and 10 g of a curing agent (Trade name: EPOMOUNT curing agent, manufactured by Refine Tec Ltd.), then performing cross-section polishing using a polishing machine.

As illustrated in FIG. 3(c), an adhesive layer 10d may be formed separately as a first adhesive layer 10e and a second adhesive layer 10f. The adhesive component constituting the first adhesive layer 1e and the second adhesive layer 10f may be the same as the adhesive component constituting the adhesive layer 10 described above, but the second adhesive layer 10f is different in that the conductive particles 12 are not dispersed, that is, are not contained. Also in this case, when an adhesive layer 10d has the above-described reaction rate, and the ratio [Dp/T] of the average particle diameter Dp of the conductive particles 12 to the thickness T of the adhesive layer 10 is 0.56 to 1.2, a wiring layer in which resistance unevenness is suppressed can be formed. In the wiring forming member 1e according to this modification example, the conductive particles 12 are dispersed, that is, contained in the first adhesive layer 10e. In this case, as in the modification example illustrated in FIG. 3(b), since the conductive particles 12 are arranged on the metal layer 20 side, the conductive particles 12 can be more reliably crushed into a flat shape by the metal layer 20 in a wiring layer 1f. In addition, by unevenly distributing the conductive particles 12 on the metal layer 20 side as described above, the trapping rate of the conductive particles 12 on the wiring (electrode) or the like can be improved. That is, conduction can be made more stable.

Wiring forming members 1, 1c, and 1e may further include a release film. The release film may be bonded to the surface of the adhesive layers 10,10c, and 10d opposite to the surface to which the metal layer 20 is bonded, or may be bonded to the surface of the metal layer 20 opposite to the surface to which the adhesive layers 10,10c, and 10d are bonded, or may be bonded to both of them. The first surface 20a of the metal layer 20 may be bonded to the adhesive layers 10,10c, and 10d. In this case, the wiring forming member can be easily handled, and the work efficiency at the time of forming the wiring layer using the wiring forming member can be improved.

In addition, in the above description, the case where the wiring forming member is a member formed by bonding the adhesive layer 10 and the metal layer 20 has been described as an example, but the wiring forming member in the present embodiment may include a set product in which the adhesive layer 10 and the metal layer 20 are provided as separate bodies, and the adhesive layer 10 can be bonded to the first surface 20a of the metal layer 20 during use. In this case, since the adhesive layer 10 and the metal layer 20 can be separately prepared (as a set of wiring forming members), it is possible to improve the degree of freedom in work when preparing the wiring layer using the wiring forming member, such as selecting a wiring forming member having a more optimal material configuration.

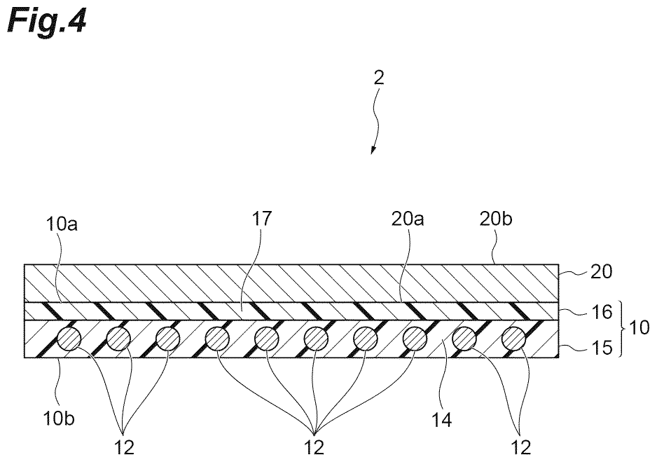

FIG. 4 is a cross-sectional view illustrating a wiring forming member according to another embodiment of the present disclosure. A wiring forming member 2 illustrated in FIG. 4 includes the adhesive layer 10 containing the conductive particles 12 and the metal layer 20. The adhesive layer 10 includes a first adhesive layer 15 containing the conductive particles 12 and the adhesive component 14, and a second adhesive layer 16 containing an adhesive component 17.

The first adhesive layer 15 includes the conductive particles 12 and the insulating adhesive component 14 in which the conductive particles 12 are dispersed. The adhesive component 14 is similar to that described above.

The second adhesive layer 16 contains the insulating adhesive component 17. The insulating adhesive component 17 in the second adhesive layer 16 may be the same as or different from the adhesive component 14. The adhesive component 17 of the second adhesive layer 16 is defined as a solid content other than conductive particles. The second adhesive layer 16 may be in the B-stage state, that is, the semi-cured state, before the wiring layer is formed by the wiring forming member 2.

In the present embodiment, the reactivity of the first adhesive layer 15 and the second adhesive layer 16 may be adjusted so that the adhesive layer 10 has the above reaction rate, and the average particle diameter of the conductive particles 12 and the thicknesses of the first adhesive layer 15 and the second adhesive layer 16 may be adjusted so that the ratio [Dp/T] of the average particle diameter Dp of the conductive particles 12 to the thickness T of the adhesive layer 10 falls within the above range.

A thickness d1 of the first adhesive layer 15 may be 0.56 to 1.2 times, 0.56 to 1.0 times, or 0.56 to 0.80 times the average particle diameter Dp of the conductive particles 12.

The thickness of the first adhesive layer 15 may be 1 to 70 μm, 1 to 60 μm, or 1 to 50 μm.

The thickness of the second adhesive layer 16 may be 0 to 50 μm, 0 to 40 μm, or 0 to 30 μm.

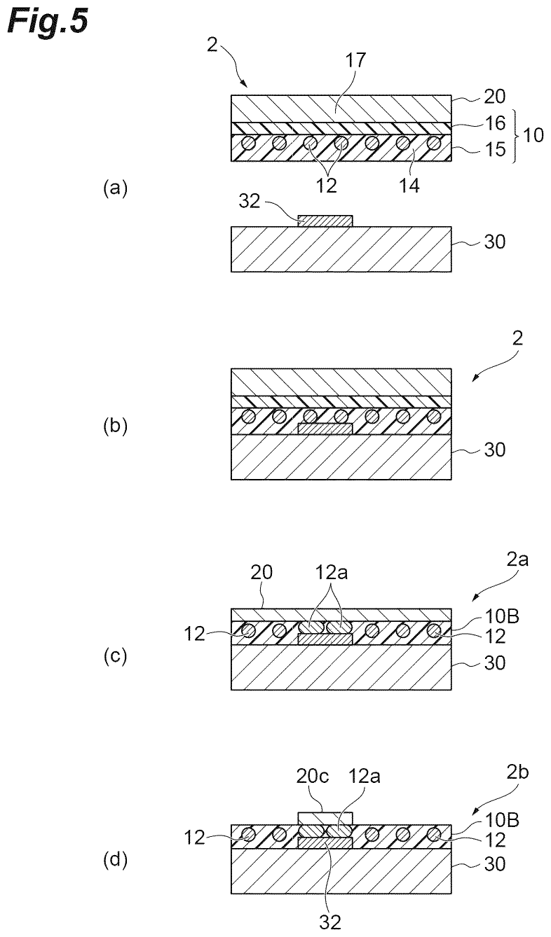

Next, a method for forming a wiring layer using the wiring forming member 2 described above will be described with reference to FIG. 5. FIGS. 5(a) to 5(d) are views illustrating a method for forming a wiring layer using the wiring forming member illustrated in FIG. 4.

First, as illustrated in FIG. 5(a), the wiring forming member 2 is prepared. Furthermore, a base material 30 on which a wiring 32 is formed is prepared. Then, the wiring forming member 2 is disposed such that the adhesive layer 10 side of the wiring forming member 2 faces the base material 30. Thereafter, as illustrated in FIG. 5(b), lamination is performed to cover the wiring 32, and the wiring forming member 2 is attached onto the base material 30.

Subsequently, as illustrated in FIG. 5(c), predetermined heating and pressurization are performed on the wiring forming member 2, and pressure bonding is performed on the base material 30. At this time, when the first surface 20a of the metal layer 20 of the wiring forming member 2 is flat, the conductive particles 12 required to ensure conductivity can be more reliably deformed into flat conductive particles 12a. In a pressure-bonded wiring forming member 2a, the conductive particles 12a flattened on the wiring 32 (thereby, the insulating layer is broken to expose the conduction portion) are disposed, and reliable electrical conduction between the metal layer 20 and the wiring 32 is achieved. At this time, the adhesive layer 10 is also crushed to become a thinner adhesive layer 10B. In addition, since the adhesive layer 10 includes the first adhesive layer 15 in which conductive particles are included in the adhesive component and the second adhesive layer 16, good insulation reliability in the thickness direction of a portion that is not desired to be conductively connected is achieved.

Subsequently, as illustrated in FIG. 5(d), predetermined patterning processing (for example, etching processing) is performed on the metal layer 20, and processing is performed into a predetermined wiring pattern 20c (another wiring). At this time, the second surface 20b of the metal layer 20 may be treated to be a smooth surface. The above-described processing steps of FIG. 5(a) to 5(d) may be repeated a predetermined number of times to form the wiring layer.

That is, a method for forming a wiring layer using a wiring forming member includes a process of preparing a wiring forming member, a process of preparing a base material on which a wiring is formed, a process of arranging the wiring forming member such that an adhesive layer side faces a substrate with respect to a surface of the base material on which the wiring is formed to cover the wiring, a process of thermocompression-bonding the wiring forming member to the base material, and a process of performing patterning processing on the metal layer.

Thus, a wiring formed member 2b is formed. The wiring formed member 2b includes the base material 30 having the wiring 32, and the cured product of the first adhesive layer 15 and the second adhesive layer 16 of the wiring forming member 2 disposed on the base material 30 to cover the wiring 32 (an adhesive layer of a thermocompression-bonded wiring forming member). In the wiring formed member 2b, the wiring 32 and the metal layer 20 of the wiring forming member 2 or the wiring pattern 20c formed (for example, etched) from the metal layer 20 are electrically connected by the conductive particles 12a. When the processing steps of FIG. 5(a) to 5(d) are repeated a predetermined number of times, the wiring formed member 2b may have a configuration including a plurality of wiring layers (layers in which the above-described wirings are connected to each other).

As described above, according to the method for forming the wiring layer using the wiring forming member 2 according to the present embodiment, the process for forming the wiring layer connecting the wirings can be simplified as compared with the conventional process for performing laser processing, filled plating processing, and the like. In addition, the formed wiring layer can be easily thinned.

Furthermore, according to the method for forming a wiring layer using the wiring forming member 2 according to the present embodiment, when the adhesive layer 10 has the above-described reaction rate, and the ratio [Dp/T] of the average particle diameter Dp of the conductive particles 12 to the thickness T of the adhesive layer 10 is 0.56 to 1.2, a wiring layer in which resistance unevenness is suppressed can be formed.

Furthermore, according to the method for forming a wiring layer using the wiring forming member 2 according to the present embodiment, the degree of freedom in designing a wiring pattern when forming a wiring layer can be sufficiently secured by the following effects.
(i) Since the adhesive layer 10 includes the second adhesive layer 16, even in a case where the wiring layer formed by patterning the metal layer 20 has a portion that is not desired to be conductively connected in the lamination direction (or the thickness direction of the adhesive layer), insulation reliability in the portion can be easily secured.
(ii) In the wiring layer formed by patterning the metal layer 20 or the redistribution layer separately formed, the conductive particles 12 are less likely to come into contact with a portion other than the conductively connected portion, and it is easy to suppress the electric transmission loss of the wiring due to the contact of the conductive particles.

The above effect will be described with reference to the drawings.

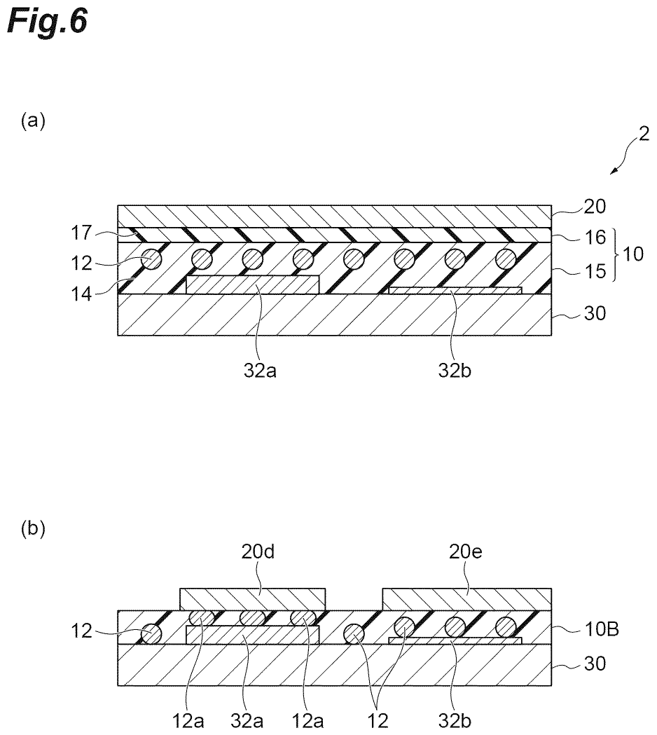

FIGS. 6(a) and 6(b) are cross-sectional views for illustrating an example of a case where a wiring layer is formed using the wiring forming member 2 according to the present embodiment.

FIG. 6(a) illustrates a state in which the base material 30 having a wiring pattern 32a and a wiring pattern 32b is prepared, and the wiring forming member 2 is disposed such that the adhesive layer 10 side faces the base material 30 with respect to the surface of the base material 30 on which the wiring pattern is formed to cover the wiring patterns 32a and 32b. Thereafter, through the process of thermocompression-bonding the wiring forming member 2 to the base material 30 and the process of performing patterning processing on the metal layer 20, a wiring formed member in which a wiring pattern 20d conductively connected to the wiring pattern 32a and a wiring pattern 20e that is not desired to be conductively connected to the wiring pattern 32b are formed as illustrated in FIG. 6(b) is obtained.

Here, since the adhesive layer 10 of the wiring forming member 2 includes the first adhesive layer 15 containing the conductive particles 12 and the adhesive component 14 and the second adhesive layer 16 not containing the conductive particles and containing the adhesive component 17, it is possible to provide an adhesive layer 18a with a thickness capable of securing a distance in which conduction by the conductive particles 12 does not occur between the wiring pattern 20e and the wiring pattern 32b that are not desired to be conductively connected while securing good conduction between the wiring of the wiring pattern 20d and the wiring pattern 32a via the conductive particles 12 at the time of pressure-bonding. Thus, the wiring pattern 20e and the wiring pattern 32b are not conductively connected, and insulation reliability in the thickness direction of the adhesive layer can be secured.

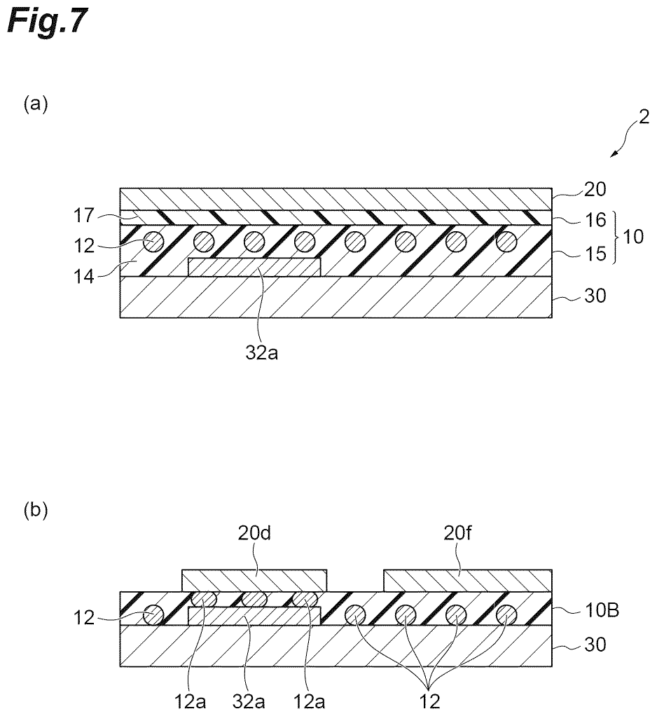

FIGS. 7(a) and 7(b) are cross-sectional views for illustrating another example of a case where a wiring layer is formed using the wiring forming member 2 according to the present embodiment.

FIG. 7(a) illustrates a state in which the base material 30 having the wiring pattern 32a is prepared, and the wiring forming member 2 is disposed such that the adhesive layer 10 side faces the base material 30 with respect to the surface of the base material 30 on which the wiring pattern is formed to cover the wiring pattern 32a. Thereafter, through the process of thermocompression-bonding the wiring forming member 2 to the base material 30 and the process of performing patterning processing on the metal layer 20, a wiring formed member in which the wiring pattern 20d conductively connected to the wiring pattern 32a and a wiring pattern 20f (or a portion not conductively connected in the wiring pattern) not conductively connected are formed as illustrated in FIG. 7(b) is obtained.

Here, since the adhesive layer 10 of the wiring forming member 2 includes the first adhesive layer 15 containing the conductive particles 12 and the adhesive component 14 and the second adhesive layer 16 not containing the conductive particles but containing the adhesive component 17, it is possible to provide the adhesive layer 18a in which the wiring pattern 20f and the conductive particles 12 are not in contact with each other while ensuring good conduction between the wiring of the wiring pattern 20d and the wiring pattern 32a via the conductive particles 12 at the time of pressure-bonding. As a result, in the wiring pattern 20f, the electric transmission loss of the wiring due to the contact of the conductive particles can be suppressed. In particular, in the wiring forming member 2, since the metal layer 20, the second adhesive layer 16, and the first adhesive layer 15 are laminated in this order, it is easy to prevent contact between the wiring pattern 20f and the conductive particles 12.

In the method illustrated in FIG. 7, the wiring pattern 20f may be formed by a process of performing patterning processing on the metal layer 20 and a process of forming rewiring.

In the first adhesive layer 15 of the wiring forming member 2 illustrated in FIG. 4, the conductive particles 12 are locally arranged, but the conductive particles 12 may be randomly or on average dispersed in the adhesive component 14.

In the first adhesive layer 15 of the wiring forming member 2, the conductive particles 12 may be locally disposed on the second adhesive layer 16 side, or the conductive particles 12 may be locally disposed on the opposite side to the second adhesive layer 16 side (the second surface 10b side of the adhesive layer 10).

Although the second adhesive layer 16 of the wiring forming member 2 does not contain conductive particles, the second adhesive layer 16 may contain a part of the particle body of the conductive particles 12 (in other words, the conductive particles 12 may not include the entire particle body).

The adhesive layer 10 of the wiring forming member 2 may be composed of two layers of the first adhesive layer 15 and the second adhesive layer 16, or may be composed of three or more layers including a layer (for example, a third adhesive layer) other than the first adhesive layer 15 and the second adhesive layer 16. The third adhesive layer may be a layer having a composition similar to the composition described above for the first adhesive layer 15 or the second adhesive layer 16, and may be a layer having a thickness similar to the thickness described above for the first adhesive layer 15 or the second adhesive layer 16. For example, the wiring forming member 2 may be configured by laminating a metal layer, a third adhesive layer, a second adhesive layer, and a first adhesive layer in this order, or may be configured by laminating a metal layer, a second adhesive layer, a first adhesive layer, and a third adhesive layer in this order, but is not limited thereto.

In addition, the wiring forming member 2 may further include a release film. The release film may be bonded to the side opposite to the surface of the adhesive layer 10 to which the metal layer 20 is bonded (the second surface 10b side of the adhesive layer 10), or may be bonded to the side opposite to the surface of the metal layer 20 to which the adhesive layer 10 is bonded (the first surface 20a of the metal layer) (the second surface 20b side of the metal layer 20), or may be bonded to both of them. In this case, the wiring forming member can be easily handled, and the work efficiency at the time of forming the wiring layer using the wiring forming member can be improved.

In addition, in the above description, the case where the wiring forming member is a member formed by bonding the adhesive layer 10 and the metal layer 20 has been described as an example, but the wiring forming member 2 in the present embodiment may include a set product in which the adhesive layer 10 and the metal layer 20 are provided as separate bodies, and the adhesive layer 10 can be bonded to the first surface 20a of the metal layer 20 during use. In this case, since the adhesive layer 10 and the metal layer 20 can be separately prepared (as a set of wiring forming members), it is possible to improve the degree of freedom in work when preparing the wiring layer using the wiring forming member, such as selecting a wiring forming member having a more optimal material configuration.

### EXAMPLES

Hereinafter, the present disclosure will be described more specifically with reference to examples. However, the present disclosure is not limited to these examples.

### Synthesis Example 1: Synthesis of Modified Polymaleimide Compound

100 g of diamine-modified siloxane at both terminals (Trade name: X-22-161 A, functional group equivalent of amino group, manufactured by Shin-Etsu Chemical Co., Ltd.: 800 g/mol), 450 g of 2,2-bis[4-(4-maleimidophenoxy)phenyl]propane, and 550 g of propylene glycol monomethyl ether were put in a reaction vessel having a volume of 2 L that can be heated and cooled and equipped with a thermometer, a stirring device, and a water content meter with a reflux condenser, and then the mixture was reacted at 120° C. for 3 hours to obtain a solution containing a modified polymaleimide compound. The weight average molecular weight (Mw) of the obtained modified maleimide resin was 2500.

### <Preparation of Adhesive Component>

As adhesive components, the following thermosetting components, fillers, and antioxidants were prepared.

### (Thermosetting Component)

Epoxy resin A: NC-3000H (Trade name, manufactured by Nippon Kayaku Co., Ltd., Biphenyl novolac-type epoxy resin, epoxy equivalent: 289 g/eq)
Epoxy resin B: NC-7000L (Trade name, manufactured by Nippon Kayaku Co., Ltd., Naphthol aralkyl cresol copolymer epoxy resin, epoxy equivalent: 230 g/eq)
Phenol resin A: KA-1165 (Trade name, manufactured by DIC Corporation, Cresol novolac-type phenol resin, hydroxyl group equivalent: 119 g/eq)
The hydroxyl group equivalent of the phenol resin was determined by the following measurement method.
Maleimide compound A: Modified polymaleimide compound of Synthesis Example 1
Curing accelerator A: G-8009L (trade name, manufactured by DKS Co., Ltd., Isocyanate mask imidazole)

### (Filler)

Silica particles A: SC-2050 (KC) (trade name, manufactured by Admatechs Co., Ltd., Fused spherical silica, average particle diameter: 0.5 μm)

### (Antioxidant)

Antioxidant A: YOSHINOX BB (Trade name, manufactured by Mitsubishi Chemical Group Corporation, Phenol derivative)

### <Method for Measuring Hydroxyl Group Equivalent>

1 g of a sample was weighed precisely into a round-bottom flask, and 5 mL of acetic anhydride and a pyridine test solution are further weighed accurately. Next, the flask was then equipped with an air cooler and heated at 100° C. for 1 hour. After cooling the flask, 1 mL of water was added, and the flask was heated again at 100° C. for 10 minutes. After re-cooling the flask, the air cooler and the neck of the flask were washed with 5 mL of neutralized methanol, and 1 mL of a phenolphthalein reagent was added. The thus-obtained solution was titrated using a 0.1 mol/L potassium hydroxide-ethanol solution to determine the hydroxyl value. From the obtained hydroxyl value, the hydroxyl equivalent (g/eq) in terms of mass per 1 mol (1 eq) of hydroxyl group was calculated.

### <Preparation of Conductive Particles>

The following were prepared as conductive particles.

### (Conductive Particles 1)

As conductive particles 1, gold plated resin particles (resin material: styrene-divinylbenzene copolymer) and conductive particles having an average particle diameter of 20 μm and a specific gravity of 1.7 were prepared.

### (Conductive Particles 2)

As the conductive particles 2, Ni particles, conductive particles having an average particle diameter of 20 μm and a specific gravity of 8.9 were prepared.

### (Conductive Particles 3)

Cu particles, conductive particles having an average particle diameter of 20 μm and a specific gravity of 8.9 were prepared as the conductive particles 3.

### (Conductive Particles 4)

Cu particles, conductive particles having an average particle diameter of 10 μm and a specific gravity of 8.9 were prepared as the conductive particles 4.

### <Production of Wiring Forming Member>

### Example 1

In 13.05 g of methyl ethyl ketone (MEK), 23.12 g of the epoxy resin A, 9.52 g of the phenol resin A, and 0.065 g of the curing accelerator A were dissolved, and then 12.56 g of the silica particles A and 8.23 g of the conductive particles 1 were added to prepare a coating liquid for forming an adhesive layer.

This coating liquid was applied to one surface (surface roughness Rz: 3.0 μm) of copper foil (Trade name: 3EC-M3-VLP, manufactured by Mitsui Mining & Smelting Corporation, thickness: 12 μm) using a coating apparatus (manufactured by Yasui Seiki Inc., product name: precision coater), and hot-air dried at 160° C. for 10 minutes to provide a 19 μm-thick adhesive layer on the copper foil. In this way, a wiring forming member of Example 1 was produced.

### Examples 2 to 4

Except that an adhesive layer was provided with a thickness (24 μm, 32 μm, 20 μm) as shown in Table 1, the same procedure as in Example 1 was carried out to prepare each wiring forming member.

### Example 5

A wiring forming member was prepared in the same manner as in Example 1 except that the blending amount of the conductive particles 1 was changed to 3.81 g and the adhesive layer was provided with the thickness (20 μm) shown in Table 1.

### Example 6

A wiring forming member was prepared in the same manner as in Example 1 except that the blending amount of the conductive particles 1 was changed to 2.49 g and the adhesive layer was provided with the thickness (20 μm) shown in Table 1.

### Example 7

A wiring forming member was prepared in the same manner as in Example 1 except that 1.76 g of the conductive particles 2 were blended instead of the conductive particles 1, and the adhesive layer was provided with the thickness (18 μm) shown in Table 2.

### Examples 8 to 10

Except that an adhesive layer was provided with a thickness (20 μm, 25 μm, 30 μm) as shown in Table 2, the same procedure as in Example 7 was carried out to prepare each wiring forming member.

### Example 11

A wiring forming member was prepared in the same manner as in Example 1 except that 3.22 g of the conductive particles 3 were blended instead of the conductive particles 1, and the adhesive layer was provided with the thickness (20 μm) shown in Table 2.

### Example 12

A wiring forming member was prepared in the same manner as in Example 11 except that the blending amount of the conductive particles 3 was changed to 1.57 g.

### Example 13

A wiring forming member was prepared in the same manner as in Example 11 except that the blending amount of the conductive particles 3 was changed to 1.03 g.

### Example 14

A wiring forming member was produced in the same manner as in Example 11 except that the adhesive layer was provided with the thickness (25 μm) shown in Table 3.

### Example 15

A wiring forming member was produced in the same manner as in Example 12 except that the adhesive layer was provided with the thickness (25 μm) shown in Table 3.

### Example 16

A wiring forming member was produced in the same manner as in Example 13 except that the adhesive layer was provided with the thickness (25 μm) shown in Table 3.

### Example 17

A wiring forming member was produced in the same manner as in Example 11 except that the adhesive layer was provided with the thickness (30 μm) shown in Table 3.

### Example 18

A wiring forming member was produced in the same manner as in Example 12 except that the adhesive layer was provided with the thickness (30 μm) shown in Table 3.

### Example 19

A wiring forming member was produced in the same manner as in Example 11 except that the adhesive layer was provided with the thickness (35 μm) shown in Table 4.

### Example 20

A wiring forming member was prepared in the same manner as in Example 1 except that 3.22 g of the conductive particles 4 were blended instead of the conductive particles 1, and the adhesive layer was provided with the thickness (16 μm) shown in Table 4.

### Example 21

A wiring forming member was prepared in the same manner as in Example 20 except that the blending amount of the conductive particles 4 was changed to 1.57 g.

### Example 22

A wiring forming member was prepared in the same manner as in Example 20 except that the blending amount of the conductive particles 4 was changed to 1.03 g.

### Example 23

In 25.8 g of methyl ethyl ketone (MEK), 14.61 g of the epoxy resin B, 40.90 g of the maleimide compound A, 0.17 g of the curing accelerator A, and 0.080 g of the antioxidant A were dissolved, and then 1.03 g of the conductive particles 1 were added to prepare a coating liquid for forming an adhesive layer.

This coating liquid was applied to one surface (surface roughness Rz: 3.0 μm) of copper foil (3EC-M3-VLP, manufactured by Mitsui Mining & Smelting Corporation, thickness: 12 μm) using a coating apparatus (manufactured by Yasui Seiki Co., Ltd., product name: Precision Coater), and hot-air dried at 160° C. for 10 minutes to prepare an adhesive layer having a thickness of 20 μm on the copper foil. In this way, a wiring forming member of Example 23 was produced.

### Example 24

A wiring forming member was prepared in the same manner as in Example 23 except that 0.52 g of the conductive particles 2 were blended instead of the conductive particles 1, and the adhesive layer was provided with the thickness (25 μm) shown in Table 4.

### Comparative Example 1

A wiring forming member was produced in the same manner as in Example 1 except that the adhesive layer was provided with the thickness (37 μm) shown in Table 5.

### Comparative Example 2

A wiring forming member was produced in the same manner as in Example 7 except that the adhesive layer was provided with the thickness (16 μm) shown in Table 5.

[Measurement of Reaction Rate when Heating at 180° C. For 5 Minutes]

For the adhesive layer prepared above, the reaction rate when heated at 180° C. for 5 minutes was determined according to the following method. Apart of the adhesive layer was scraped off to obtain two pre-heating evaluation samples 5 mg. Next, one of the pre-heating evaluation samples was heated at 180° C. for 5 minutes to obtain a post-heating evaluation sample. For each of the sample for evaluation before heating and the sample for evaluation after heating, the calorific value of DSC was measured at a temperature rising rate of 10° C./min in a measurement temperature range of 30° C. to 250° C. under a nitrogen flow using a differential scanning calorimetry (DSC) device (Product name DSC7, manufactured by PerkinElmer Japan). Based on the measured calorific value of DSC, the reaction rate at the time of heating at 180° C. for 5 minutes was determined from the following formula.

$$Reaction rate = ( C x - C y ) \times 100 / Cx$$

[In the formula, Cx represents a DSC calorific value (J/g) of the evaluation sample before heating, and Cy represents a DSC calorific value (J/g) of the evaluation sample after heating.]

### [Evaluation of Wiring Forming Member]

For the wiring forming member produced above, an evaluation sample was produced and its connection resistance value was measured according to the following method, and the connection resistance value and resistance unevenness were evaluated according to the following assessment criteria.

### [Measurement of Connection Resistance Value]

### <Preparation of Evaluation Sample>

A wiring forming member was bonded to a circuit board (PWB) having three copper circuits each having a line width of 1000 μm, a pitch of 10,000 μm, and a thickness of 15 μm on an epoxy substrate containing glass cloth. These were heated and pressed at 180° C. and 2 MPa for 60 minutes using a thermocompression bonding device (Heating method: constant heat type, manufactured by Toray Engineering Co., Ltd.), and connected over a width of 2 mm to prepare a connecting body. The wiring forming members of Examples 23 and 24 were heated and pressurized at 240° C. and 2 MPa for 90 minutes.

A sample with a resist formed on the manufactured connector was immersed in an etching solution, and was swung. The etching solution was adjusted to copper chloride: 100 g/L and hydrochloric acid: 100 ml/L. Pure water washing was performed when a predetermined copper foil portion disappeared. Thereafter, the resist was peeled off to obtain a desired evaluation sample.

### <Measurement of Evaluation Sample>

The resistance value between the remaining copper foil portion on the circuit and the copper circuit on the substrate was measured with a multimeter immediately after bonding. The resistance value was indicated by an average of 37 points of resistance between the remaining copper foil portion on the circuit and the copper circuit on the substrate.

### [Criteria for Determination in Connection Resistance Value]

A: The average value of resistance values is 3 mΩ or less
B: The average value of resistance values is 10 mΩ or less
C: Average value of resistance value is more than 10 mΩ

### [Assessment Criteria for Resistance Unevenness]

A: There is no measurement point that is twice or more the average value of the resistance value
C: There is a measurement point that is twice or more the average value of the resistance value

TABLE 1

| | Example 1 | Example 2 | Example 3 | Example 4 | Example 5 | Example 6 |
|---|---|---|---|---|---|---|
| Conductive | 1 | 1 | 1 | 1 | 1 | 1 |
| particle No. | | | | | | |
| Average particle | 20 | 20 | 20 | 20 | 20 | 20 |
| diameter Dp of | | | | | | |
| conductive | | | | | | |
| particles (μm) | | | | | | |
| Thickness T of | 19 | 24 | 32 | 20 | 20 | 20 |
| adhesive layer | | | | | | |
| (μm) | | | | | | |
| Particle | 14 | 14 | 14 | 14 | 7 | 4.7 |
| concentration of | | | | | | |
| conductive | | | | | | |
| particles (% by | | | | | | |
| volume) | | | | | | |
| Reaction rate of | 66 | 66 | 65 | 67 | 66 | 64 |
| adhesive layer | | | | | | |
| (%) | | | | | | |
| Dp/T | 1.05 | 0.83 | 0.63 | 1 | 1 | 1 |
| Evaluation of | A | A | B | A | B | B |
| connection | | | | | | |
| resistance value | | | | | | |
| Evaluation of | A | A | A | A | A | A |
| resistance | | | | | | |
| unevenness | | | | | | |

TABLE 2

| | Example 7 | Example 8 | Example 9 | Example 10 | Example 11 | Example 12 |
|---|---|---|---|---|---|---|
| Conductive | 2 | 2 | 2 | 2 | 3 | 3 |
| particle No. | | | | | | |
| Average particle | 20 | 20 | 20 | 20 | 20 | 20 |
| diameter Dp of | | | | | | |
| conductive | | | | | | |
| particles (μm) | | | | | | |
| Thickness T of | 18 | 20 | 25 | 30 | 20 | 20 |
| adhesive layer | | | | | | |
| (μm) | | | | | | |
| Particle | 7 | 7 | 7 | 7 | 6 | 3 |
| concentration of | | | | | | |
| conductive | | | | | | |
| particles (% by | | | | | | |
| volume) | | | | | | |
| Reaction rate of | 65 | 66 | 65 | 64 | 65 | 66 |
| adhesive layer | | | | | | |
| (%) | | | | | | |
| Dp/T | 1.11 | 1 | 0.8 | 0.67 | 1 | 1 |
| Evaluation of | A | A | A | B | A | A |
| connection | | | | | | |
| resistance value | | | | | | |
| Evaluation of | A | A | A | A | A | A |
| resistance | | | | | | |
| unevenness | | | | | | |

TABLE 3

| | Example 13 | Example 14 | Example 15 | Example 16 | Example 17 | Example 18 |
|---|---|---|---|---|---|---|
| Conductive | 3 | 3 | 3 | 3 | 3 | 3 |
| particle No. | | | | | | |
| Average particle | 20 | 20 | 20 | 20 | 20 | 20 |
| diameter Dp of | | | | | | |
| conductive | | | | | | |
| particles (μm) | | | | | | |
| Thickness T of | 20 | 25 | 25 | 25 | 30 | 30 |
| adhesive layer | | | | | | |
| (μm) | | | | | | |
| Particle | 2 | 6 | 3 | 2 | 6 | 3 |
| concentration of | | | | | | |
| conductive | | | | | | |
| particles (% by | | | | | | |
| volume) | | | | | | |
| Reaction rate of | 64 | 65 | 63 | 64 | 66 | 64 |
| adhesive layer | | | | | | |
| (%) | | | | | | |
| Dp/T | 1 | 0.8 | 0.8 | 0.8 | 0.67 | 0.67 |
| Evaluation of | A | A | A | B | A | B |
| connection | | | | | | |
| resistance value | | | | | | |
| Evaluation of | A | A | A | A | A | A |
| resistance | | | | | | |
| unevenness | | | | | | |

TABLE 4

| | Example 19 | Example 20 | Example 21 | Example 22 | Example 23 | Example 24 |
|---|---|---|---|---|---|---|
| Conductive | 3 | 3 | 3 | 3 | 1 | 2 |
| particle No. | | | | | | |
| Average particle | 20 | 10 | 10 | 10 | 20 | 20 |
| diameter Dp of | | | | | | |
| conductive | | | | | | |
| particles (μm) | | | | | | |
| Thickness T of | 35 | 16 | 16 | 16 | 20 | 25 |
| adhesive layer | | | | | | |
| (μm) | | | | | | |
| Particle | 6 | 6 | 3 | 2 | 14 | 7 |
| concentration of | | | | | | |
| conductive | | | | | | |
| particles (% by | | | | | | |
| volume) | | | | | | |
| Reaction rate of | 65 | 65 | 64 | 65 | 34 | 37 |
| adhesive layer | | | | | | |
| (%) | | | | | | |
| Dp/T | 0.57 | 0.63 | 0.63 | 0.63 | 1 | 0.8 |
| Evaluation of | B | A | A | B | A | A |
| connection | | | | | | |
| resistance value | | | | | | |
| Evaluation of | A | A | A | A | A | A |
| resistance | | | | | | |
| unevenness | | | | | | |

TABLE 5

| | Comparative | Comparative |
|---|---|---|
| | Example 1 | Example 2 |
| Conductive | 1 | 2 |
| particle No. | | |
| Average particle | 20 | 20 |
| diameter Dp of | | |
| conductive | | |
| particles (μm) | | |
| Thickness T of | 37 | 16 |
| adhesive layer | | |
| (μm) | | |
| Particle | 14 | 7 |
| concentration of | | |
| conductive | | |
| particles (% by | | |
| volume) | | |
| Reaction rate of | 66 | 65 |
| adhesive layer | | |
| (%) | | |
| Dp/T | 0.54 | 1.25 |
| Evaluation of | C | A |
| connection | | |
| resistance value | | |
| Evaluation of | C | C |
| resistance | | |
| unevenness | | |

### REFERENCE SIGNS LIST

1a, 1c, 1e Wiring forming member
1d, 1f Wiring layer
1b Wiring formed member
2 Wiring forming member
10, 10c, 10d, 10A, 10B Adhesive layer
10a First surface
10b Second surface
10e First adhesive layer
10f Second adhesive layer
12, 12a Conductive particles
14 Adhesive component
15 First adhesive layer
16 Second adhesive layer
17 Adhesive component
20 Metal layer
20a First surface
20b Second surface
30 Base material
32 Wiring

1. A wiring forming member comprising: a metal layer; and an adhesive layer disposed on the metal layer, wherein
the adhesive layer contains conductive particles and a thermosetting resin,
the adhesive layer has a reaction rate of 90% or less when heated at 180° C. for 5 minutes, and
a ratio [Dp/T] of an average particle diameter Dp of the conductive particles to a thickness T of the adhesive layer is 0.56 to 1.2.

2. The wiring forming member according to claim 1, wherein the thermosetting resin contains an epoxy resin and a phenol resin.

3. The wiring forming member according to claim 2, wherein the phenol resin has a hydroxyl equivalent of 300 g/eq or less.

4. The wiring forming member according to claim 1, wherein the adhesive layer further contains a filler.

5. The wiring forming member according to claim 1, wherein the adhesive layer further contains a maleimide compound.

6. The wiring forming member according to claim 1, further comprising a release film.

7. A wiring forming member in which an adhesive layer and a metal layer are provided separately, and the adhesive layer can adhere to the metal layer during use, wherein
the adhesive layer includes conductive particles and a thermosetting resin,
the adhesive layer has a reaction rate of 90% or less when heated at 180° C. for 5 minutes, and
a ratio [Dp/T] of an average particle diameter Dp of the conductive particles to a thickness T of the adhesive layer is 0.56 to 1.2.

8. The wiring forming member according to claim 7, wherein the thermosetting resin contains an epoxy resin and a phenol resin.

9. The wiring forming member according to claim 8, wherein the phenol resin has a hydroxyl equivalent of 300 g/eq or less.

10. The wiring forming member according to claim 7, wherein the adhesive layer further contains a filler.

11. The wiring forming member according to claim 7, wherein the adhesive layer further contains a maleimide compound.

12. A method for forming a wiring layer, the method comprising:
a process of preparing the wiring forming member according to claim 1;
a process of preparing a base material on which a wiring is formed;
a process of arranging the wiring forming member such that the adhesive layer faces the base material with respect to a surface of the base material on which the wiring is formed to cover the wiring;
a process of thermocompression-bonding the wiring forming member to the base material; and
a process of performing patterning processing on the metal layer.

13. A wiring formed member comprising:
a base material having a wiring; and
a cured product of the adhesive layer of the wiring forming member according to claim 1, the cured product being disposed on the base material to cover the wiring, wherein
the wiring is electrically connected to the metal layer of the wiring forming member or another wiring formed from the metal layer.
